(19) United States
(12) Patent Application Publication
(10) Pub. No.: US 2020/0055233 A1
(43) Pub. Date: Feb. 20, 2020

(54) METHOD AND SYSTEM FOR 3D PRINTING OF ELECTRICALLY CONDUCTIVE POLYMER STRUCTURES

(71) Applicant: THE UNIVERSITY OF WESTERN ONTARIO, LONDON, ONTARIO (CA)

(72) Inventors: ANDREW THOMAS CULLEN, KOMOKA (CA); AARON DAVID PRICE, LONDON (CA)

(21) Appl. No.: 16/499,404

(22) PCT Filed: Mar. 28, 2018
(86) PCT No.: PCT/CA2018/050383

§ 371 Date: Sep. 30, 2019

Related U.S. Application Data
(60) Provisional application No. 62/477,625, filed on Mar. 28, 2017.

(51) Int. Cl. B29C 64/135; B29C 64/245; B29C 64/255; B29C 64/371; B29C 64/268; G03F 7/00; G03F 7/004; G03F 7/038

(52) U.S. Cl. CPC B29C 64/135; B29C 64/245; B29C 64/255; B29C 64/371; B29K 2063/00; G03F 7/0037; G03F 7/0047; G03F 7/038; B29K 2065/00; B29C 64/268

(57) ABSTRACT

The present disclosure provides a method for producing electrically conductive 3D structures by immersing a substrate having a build surface into a vat containing a liquid photopolymer resin which includes a conjugated polymer, controlling a thickness of a layer of the liquid photopolymer resin on the build surface so that when the liquid photopolymer resin is photopolymerized a base layer of preselected thickness of resin is produced, followed by projecting a beam of radiation having a preselected pattern down onto a top surface of the first layer of the liquid photopolymer resin for long enough to effect photopolymerization of the layer of liquid photopolymer resin; and repeating step a), b) and c) a plurality of times on top of the base layer such each layer of the 3D object is selectively photopolymerized on top of the previously photopolymerized layer to produce the 3D structure. The presence of the conjugated polymer results in the final 3D structure exhibiting electrical conductivity.

### FIELD

The present disclosure relates to a method and system for the fabrication of 3D intrinsically conductive polymer structures via vat photopolymerization additive manufacturing.

### BACKGROUND

Intrinsically conductive polymers (ICP) are a class of smart materials that are electrically and ionically conductive. Ions can diffuse throughout the polymer when an electric potential is applied to produce actuation as a result of volumetric expansion and contraction. This property has drawn researchers to investigate this material for its potential within advanced sensing and actuation technologies.

The conducting polymer polypyrrole (PPy) cannot be fabricated by traditional polymer forming methods due to its insoluble and infusible properties. Consequently, the polymer is traditionally produced using in situ polymerization such as chemical, electrochemical, and photopolymerization techniques. In particular, electropolymerization has seen considerable attention due to its ability to form thin polymer films or coatings with desirable electro-mechanical properties (see references 1, 2). The monolithic nature of these films constrain devices manufactured via this process to simple linear or bending actuation modes, which has hindered their adoption in devices requiring more complex actuation tasks such as torsion or multiple degree-of-freedom actuation. There is a clear need to develop a new fabrication method for the synthesis of PPy in the form of active 3D structures which are capable of complex actuation modes. The present inventors have previously reported the ability to fabricate ICP structures using the vat polymerization additive manufacturing technique (see references 3, 19). This technique successively photopolymerizes 2D layers of polymer to fabricate 3D structures with complex features. The rapid advancement of 3D printing technology has enabled equipment capable of producing 3D objects with a high resolution. The creation of fine features are sought after with this fabrication technique since the response time of conductive polymer devices is highly dependent on the diffusion distance of ions through the material (see reference 4). 3D conductive polymer devices will be capable of producing complex actuation motions which will ultimately open up a new class of ICP actuators.

### Review of Vat Polymerization Additive Manufacturing

The vat polymerization additive manufacturing technique is commonly used in commercial and research additive manufacturing systems to create high-resolution 3D structures. This technique uses either a laser or projection system to selectively cure 2D layers of a photosensitive polymer resin to build up 3D objects layer-by-layer. The stereolithography (SLA) technique uses a laser scanned over the 2D curing plane to cure the photopolymer while the projection based systems cure the full 2D layer at once by projecting an image onto the 2D curing plane leading to reduced complexity, positioning errors, and build times compared to the SLA technique. The projected image can be generated using a digital light processing (DLP) light engine which consists of a micromirror array to reflect the light of each pixel toward or away from the output to display the desired image. Liquid crystal displays (LCD) technology can also be used as a dynamic mask to generate the projected imaged. The advantage of DLP projection systems over LCD displays is the superior black level which prevents photopolymerization outside the desired areas (see reference 20).

Vat polymerization additive manufacturing techniques use either a fixed-surface or free-surface method. For the fixed-surface method, seen in FIG. 1, light (40) is projected up from below through a window (32) in a vat (10) containing a photopolymer resin (14). Thin layers of the photopolymer formulation are selectively cured between the window (32) and the previously cured layers to form the 3D object upside down. Thus, the fixed-surface method requires each layer to be peeled off the window (32) in the vat (10) prior to the next layer being grown on the top surface of the window (32) between the window and the layer that was just peeled off. The free-surface method, seen in FIG. 2, light (40) is projected down onto a vat (10) containing the photopolymer resin (14). Each layer of the 3D object is selectively cured on top of the previously cured layer to create the 3D object right-side up. In both methods, the first layer (50) is cured on the build surface (12) before the second (52) and subsequent layers (54) are successively built upon the previously cured layer.

The fixed-surface method often requires a non-stick coating on the window (32) to reduce adhesion between the cured polymer layer and the window. This technique is not well suited for low stiffness materials because the layers will tear apart during the peeling process. The fixed-surface technique is preferred for commercial systems since it provides precise control over the cured layer thickness with the use of a linear stage. Various techniques have been investigated to reduce the peeling force between the newly cured polymer layer and the window, the most popular of which is to use an oxygen permeable material on the window to create an uncured dead zone just above the window. Oxygen dissolved in a liquid photopolymer resin will react with radicals generated from the photoinitiator, drastically inhibiting polymerization. Transparent and oxygen permeable polymers such as polydimethylsiloxane (PDMS) are commonly used as an oxygen permeable film on the window. The film is usually aerated every layer by squeegeeing off the liquid photopolymer so the oxygen within the film can be replenished.

The free-surface method eliminates the problem of peeling forces by curing the polymer layer on top of the previously cured layer. A thin layer of the photopolymer resin is created by either lowering the build surface (12) further down into the vat (10) or dispensing more polymer resin into the vat (10). This method, however, requires more advanced techniques to control the cured layer thickness due to surface tension forces between the photopolymer resin and the previously cured layer (see reference 17). Wiper based lamination techniques are typically utilized to form thin polymer layers with a high precision. Alternatively, the viscosity of the photopolymer can be reduced to minimize non-uniformity due to the reduced surface tension. Consideration must also be given to oxygen inhibition with the free-surface technique since the curing layer is exposed to air. The vat is typically blanketed with an inert gas to compensate for this effect (see reference 18).

Fabricating multi-material structures with light-based processes is more challenging compared to extrusion additive manufacturing techniques, but several groups have found effective solutions due to the advantages of multi-material printing. Most implementations of multi-material vat polymerization additive manufacturing systems have multiple polymer vats filled with different photopolymers. The multi-material feature is valuable for multi-coloured parts, components with varying mechanical properties for applications such as hard cases with soft ergonomic grips, and components with embedded electrical connections by using a photopolymer with a conductive filler.

### Review of Photopolymerization

The photopolymer formulation used within the vat polymerization additive manufacturing technique must be carefully designed to meet the material property requirements for the target application while also being compatible with the fabrication technique so the desired structures can be created.

Photopolymer formulations typically consist of monomers, oligomers, and a photoinitiating system which initiates chain growth polymerization to convert the monomers and oligomers into polymer molecules.

The photoinitiating system is used to generate reactive species when irradiated with light to initiate chain growth polymerization of the oligomers and monomers to form long polymer chains. The two most common classes of photoinitiators are radical and cationic.

Radical photoinitiators generate reactive free radicals upon irradiation with light to initiate polymerization of acrylate-based polymers. Radical photoinitiators are highly reactive leading to fast cure times.

Cationic photoinitiators are used to polymerize epoxy-based polymers. Cationic photoinitiators generate a protonic acid (Bronsted or Lewis acid) when irradiated with light to initiate a ring opening reaction with epoxy monomers. The cationic polymerization reaction is slower compared to radical photoinitiation but has some other beneficial properties. The reactive species generated by the cationic polymerization chemistry are insensitive to oxygen allowing it to be used in a wider range of applications. The reactive cations are stable for a longer period resulting in a “dark cure” after the initiating light has been turned off which results in a higher degree of curing.

Oligomers are the primary component of a photosensitive polymer formulation. Oligomers are usually classified based on their polymerization mechanism. Acrylate-based oligomers are initiated with hydrogen donor reaction from a radical photoinitiator while epoxy-based oligomers are initiated by a ring opening reaction from a cationic photoinitiator. Acrylate-based oligomers can be rapidly polymerized with short irradiation times which is favorable to decrease fabrication times. The radical polymerization reaction can experience significant shrinkage of 5-20% leading to significant inaccuracies and curling of the polymer structures. Epoxy-based oligomers require longer irradiation times compared to acrylate oligomers but experience less shrinkage upon curing, around 1-2%. The dark cure property of cationic photoinitiators leads to a stiff, but brittle material compared to acrylate polymers. Most commercial polymer formulations incorporate both epoxy and acrylate oligomers to gain the benefits of each type of polymer.

Oligomers tend to have a high viscosity which can make laminating thin polymer layers challenging. Lower viscosity monomers are typically added to the polymer formulation to control the overall viscosity while also contributing to the polymerization reaction. This additive is typically referred to as a reactive diluent.

One of the most challenging features to fabricate with light-based 3D printing technology is overhangs. If the irradiated light can pass deep within the photopolymer, the layer thickness will be cured much thicker then desired. A common technique to combat this effect is to introduce a non-reactive component that absorbs light within a similar spectrum as the photoinitiator. This component will constrain light penetration to the desired layer thickness, preventing over curing when fabricating overhangs (see reference 21).

### Review of Intrinsically Conductive Polymers

An emerging area of research in the field of additive manufacturing is the development of 4D printing. In this field, the 3D printed materials can actuate in response to an external stimulus. A new potential material for 4D printing technology is intrinsically conductive polymers, also known as conjugated polymers. This type of polymer has characteristic alternating single and double bonds along the polymer chain, also referred to as conjugation. The conjugation property makes this polymer electroactive which allows various properties of the polymer to be varied electrochemically. PPy is a neutral polymer within its reduced state. When the polymer is oxidized, bond reorientation results in positive charges to form along the polymer chain. Anions diffuse into the polymer to neutralize the overall charge of the material. Within the reduced state, electrons held within the π bonds present at the double bond locations are not held as tightly held as with conventional polymers which allows this material conduct electricity. The electrical conductivity of the polymer is increased by up to 10 orders of magnitude when switched to the oxidized state since the charges developed along the polymer chain further increase the mobility of electrons along the polymer chain (see reference 22).

The diffusion of ions into the polymer to neutralize the overall charge of the material has been exploited to create actuators with conjugated polymers. The ingress and egress of ions when the polymer is switched between the oxidized and reduced states causes volumetric expansion and contraction which can be harnessed to perform mechanical work. Studies have shown that the amount of volumetric expansion and contraction can be maximized by electrochemical switching the polymer in an electrolyte solution containing cations and anions that have a relatively large size difference. For instance, when polypyrrole is operated in a solution of LiTFSI, the polymer can experience a volumetric expansion of 35% in the oxidized state (see reference 22).

Actuation of conjugated polymers is performed in an electrochemical cell containing the desired electrolyte solution. Due to the electrochemical nature of this actuator, only low voltages of ±1 V are required to operate this material. The choice of cations and anions, the solvent used in the electrolyte, and the preparation conditions of the polymer impact the performance of conjugated polymer actuators. To overcome the limitation of actuating conjugated polymers in an electrolyte solution, researchers commonly utilize a tri-layer actuator design. In this configuration, a porous membrane containing the desired electrolyte is coated with the conjugated polymer on both sides. When an electric potential is applied across the two polymer layers, ions will diffuse from one polymer layer to the other. When the potential is reversed, ions will diffuse to the other electrode. The ion driven expansion of one polymer coating and the contraction of the other will cause the device to bend in the direction of the contracted coating. This actuator configuration can be sealed, allowing the polymer to operated outside of solution.

PPy is commonly studied for sensing and actuation applications due to its large actuation strains and ease of synthesis (see reference 22). The polymerization of pyrrole is initiated by an oxidation reaction which generates reactive radicals from the pyrrole monomer. Radical monomers react with each other to form dimers. Subsequent oxidation of dimers and oligomers leads to chain growth of polypyrrole.

The oxidation reaction that initiates the polymerization of pyrrole can come from a number sources, most common of which is electrochemical and chemical polymerization methods. In electrochemical polymerization, pyrrole is oxidized at the anode electrode in an electrochemical cell. This technique yields a thin polypyrrole film deposited onto the anode electrode. In the chemical polymerization method, a strong chemical oxidant is used to oxidize pyrrole monomer. A polypyrrole precipitate is formed in this method. Polypyrrole in the form of thin films and powders is constrained to simple linear and bending actuation modes. Photopolymerization of polypyrrole is a promising technique to produce 3D structures that are capable of complex modes of actuation.

Various photosensitive polypyrrole formulations exist to polymerize pyrrole when irradiated with UV light. The photopolymerization technique is best described as photochemically initiated polymerization since this it uses reagents to oxidatively polymerize pyrrole when excited with light.

One of the first formulations to photopolymerize polypyrrole utilized a light sensitive the copper complex [Cu(dpp)]²⁺ (dpp=2,9-diphenyl-1,10-phenanthroline). The copper complex becomes excited when irradiated with UV light. When reacted with the electron acceptor p-nitrobenzyl bromide, the copper complex forms a strong oxidant to rapidly polymerize pyrrole (see reference 8).

The ruthorim complex Ru(bpy)₃²⁺ (bpy=bipyrideine) is utilized in a similar mechanism to polymerize pyrrole. The UV excited state of the ruthorim complex is reacted with an electron acceptor to generate a strong oxidant to polymerize polypyrrole. This formulation has been further developed for the fabrication of 3D microscale structures supported within a support material using the two-photon polymerization technique (see references 5-7 and 9).

Commercial photoinitiators containing an iron-arene structure, such as Irgacure 261 and Komplex KM 1144, have been found to be capable of photopolymerizing pyrrole. During photolysis, these photoinitiators form a Fe(II) compound which is rapidly oxidized in air to Fe(III), a strong oxidant, to initiate the polymerization of pyrrole (see references 13 and 23).

One of the most developed techniques to photopolymerize pyrrole is with the use of a silver salt. Ag⁺ ions like Fe³⁺ and Cu²⁺ are oxidants which can be used to chemically polymerize pyrrole. Ag⁺ is a far weaker oxidant that takes several days to chemically polymerize pyrrole. The oxidation reaction speed is greatly increased when Ag⁺ ions are excited by UV light. Silver salts like silver nitrate can be directly used as a photoinitiator for the photopolymerization of pyrrole due to its absorption peak at 220 nm (see reference 24). For use with longer wavelength light sources, a photoinitiator can be added to the formulation as an intermediate sensitizer (see reference 11). One of the advantages of silver salt based photosensitive formulations is that they produce a polymer with a relatively high conductivity compared to other photosensitive formulations. The conductivity of silver salt formulations can be as high as 0.2 S·cm (see reference 11) compared to 3·10⁻⁶ S·cm where the ruthorium complex is used (see reference 25) and 3·10⁻⁵ S·cm when iron-arene photoinitiators are utilized (see reference 23). The improved conductivity is due to the formation of silver islands during the oxidative polymerization reaction where Ag⁺ ions are reduced to silver metal.

The photopolymerization technique has a unique capability to selectively polymerize pyrrole onto conducting or non-conducting substrates and has the potential to be integrated with the vat polymerization techniques to fabricate 3D conjugated polymer structures but, this method also has some disadvantages.

The major challenge with the photopolymerization technique is the poor mechanical properties of the produced polymer. The product of photopolymerized pyrrole is a particulate, similar to the chemical polymerization method, making it difficult to create solid polymer structures of polypyrrole. When dried, the polymer is brittle, limiting its applications for actuation technologies. Efforts have been made to improve their mechanical properties by incorporating large surfactant anions (see reference 11) or simultaneous polymerization of pyrrole with another polymer (see references 10, 12-15). Hybrid polymer systems allow the overall material to take on the smart material properties of PPy and the mechanical properties of the secondary polymer.

### SUMMARY

The present disclosure provides formulations for blending polypyrrole with a flexible polymer for electrically actuatable actuator devices since the polymer experiences large volume expansion and contraction.

The present disclosure provides a method for producing an electrically conductive 3D structure, comprising:

a) immersing a substrate having a build surface into a vat containing a liquid photopolymer resin, the liquid photopolymer resin comprising a conjugated polymer, a weak oxidant metal salt, a photopolymer and a photoinitiator;

b) controlling a layer of the liquid photopolymer resin on the build surface so that when the liquid photopolymer resin is photopolymerized a base resin layer of preselected thickness is produced;

c) projecting a beam of radiation having a preselected pattern down onto a top surface of the first layer of the liquid photopolymer resin for long enough to effect photopolymerization of the layer of liquid photopolymer resin, and

repeating step a), b) and c) a plurality of times on top of the base layer such each layer of the 3D structure is selectively photopolymerized on top of the previously photopolymerized layer to produce the electrically conductive 3D structure.

The step b) of controlling a thickness of the layer of the liquid photopolymer resin may be achieved using a pump used to control the liquid photopolymer resin level in the vat or by vertically positioning the build surface within a prefilled photopolymer vat using a linear stage.

Oxygen inhibition during photopolymerization of the layer of liquid photopolymer resin may be prevented by blanketing the curing surface with an inert gas or containing the photopolymer vat within a chamber purged with an inert gas. The beam of radiation may be a light beam produced by a laser or projection system mounted above the photopolymer vat.

The beam of radiation may be produced by any one or combination of a visible light, UV, IR light source and an electron beam.

The vat may be contained within a chamber with a transparent window in the top through which the beam of radiation is directed.

The build surface may be magnetically detachable.

The conjugated polymers may include any one or combination of polypyrroles, polyanilines, polyphenylenes, polyfluorenes, polythiophenes and poly(oxythiophene)s.

The weak oxidant may be any one or combination silver salts, copper compounds, ruthenium compounds, and iron compounds.

The silver salt may be silver nitrate, silver nitrite, silver tosylate, silver perchlorate, and silver tetrafluoroborate.

The copper compound may be [Cu(dpp)]²⁺ (dpp=2,9-diphenyl-1,10-phenanthroline)

The ruthenium compound may be a ruthenium complex Ru(bpy)₃²⁺ (bpy=bipyrideine).

The iron compounds may be those present in photoinitiators Irgacure 261 and Komplex KM 1144.

The photoinitiator may include any one or combination of Trimethylbenzoyl-diphenyl-phosphine oxide (TPO), 5,7-diiodo-3-butoxy-6-fluorone photoinitiator (H-Nu 470), 2,2-dimethoxy-2-phenylacetophenone (DMPA), 2-methoxy-2-phenyl-aceto phenone (BZME) and camphorquinone (CQ).

The liquid photopolymer resin may contain photopolymer reagents such as acrylate or epoxy oligomers to form a hybrid polymer with the conjugated polymers (intrinsically conductive polymers (ICP)) which allows the overall material to take on the smart material properties of the intrinsically conductive polymers and the mechanical properties of the photopolymers.

The acrylate based photopolymers may include any one of urethane dimethylacrylate (UDMA), Bisphenol A ethoxylate dimethacrylate (BEMA) and poly(ethylene glycol) methyl ether methacrylate (PEGMA).

The epoxy based photopolymers may include Bisphenol A diglycidyl ether.

The liquid photopolymer resin may further comprises an inhibitor compound that has absorption properties similar to the photoinitiator for the purpose of reducing the depth of radiation penetration.

The liquid photopolymer resin may further comprise conductive particles. These conductive particles may include any one or combination of carbon nanotubes, graphene nanoparticles and metal nanoparticles.

The present disclosure provides a method for producing a multi-component 3D structure with one of the components being electrically conductive, comprising:

a) immersing a substrate having a build surface into a vat containing a first liquid photopolymer resin;

b) controlling a layer of the first liquid photopolymer resin on the build surface so that when the first liquid photopolymer resin is photopolymerized a base resin layer of preselected thickness is produced;

c) projecting a beam of radiation having a preselected pattern down onto a top surface of the first layer of the liquid photopolymer resin for long enough to effect photopolymerization of the layer of liquid photopolymer resin, and

d) repeating step a), b) and c) a preselected number of times on top of the base layer such each layer of the 3D structure is selectively photopolymerized on top of the previously photopolymerized layer to produce a 3D structure of preselected dimensions; and

e) repeating steps a) to d) using a second liquid photopolymer resin which is different from the first liquid photopolymer resin to give a multi-material 3D structure of preselected dimensions, wherein one of the first and second liquid photopolymer resins comprises a conjugated polymer, a weak oxidant metal salt, a photopolymer and a photoinitiator such that at least one of the materials of the multi-material 3D structure is electrically conductive.

f) cleaning the photopolymerized structures when switching between the first and second liquid photopolymer resins to prevent contamination.

The present disclosure provides a formulation for 3D printing of electrically conductive structures, comprising:

a conjugated polymer, a weak oxidant metal salt, a photopolymer and a photoinitiator, wherein upon 3D printing of the formulation followed by curing, a resulting 3D structure is electrically conductive.

The conjugated polymers may include any one or combination of polypyrroles, polyanilines, polyphenylenes, polyfluorenes, polythiophenes and poly(oxythiophene)s.

The photopolymer may include any one of acrylate based photopolymers and epoxy based photopolymers.

The acrylate based photopolymers may include any one of urethane dimethylacrylate (UDMA), Bisphenol A ethoxylate dimethacrylate (BEMA) and poly(ethylene glycol) methyl ether methacrylate (PEGMA).

The epoxy based photopolymer may include Bisphenol A diglycidyl ether.

The weak oxidant may be any one or combination silver salts, copper compounds, ruthenium compounds, and iron compounds.

The silver salt may be any one of silver nitrate, silver nitrite, silver tosylate, silver perchlorate, and silver tetrafluoroborate, and wherein the copper compound is [Cu(dpp)]²⁺ (dpp=2,9-diphenyl-1,10-phenanthroline), and wherein the ruthenium compound is a ruthenium complex Ru(bpy)₃²⁺ (bpy=bipyrideine), and wherein the iron compounds are those present in photoinitiators Irgacure 261 and Komplex KM 1144.

The photoinitiator may include any one or combination of Trimethylbenzoyl-diphenyl-phosphine oxide (TPO), 5,7-diiodo-3-butoxy-6-fluorone photoinitiator (H-Nu 470), 2,2-dimethoxy-2-phenylacetophenone (DMPA), 2-methoxy-2-phenyl-aceto phenone (BZME) and camphorquinone (CQ).

The present disclosure also provides a method for producing a multi-component 3D structure with one of the components being electrically conductive, comprising:

a) immersing a substrate having a build surface into a vat containing a first liquid photopolymer resin;

b) controlling a layer of the first liquid photopolymer resin on the build surface so that when the first liquid photopolymer resin is photopolymerized a base resin layer of preselected thickness is produced;

c) projecting a beam of radiation having a preselected pattern down onto a top surface of the first layer of the liquid photopolymer resin for long enough to effect photopolymerization of the layer of liquid photopolymer resin, and

d) repeating step a), b) and c) a preselected number of times on top of the base layer such each layer of the 3D structure is selectively photopolymerized on top of the previously photopolymerized layer to produce a 3D structure of preselected dimensions; and

e) repeating steps a) to d) using a second liquid photopolymer resin which is different from the first liquid photopolymer resin to give a multi-material 3D structure of preselected dimensions, wherein one of the first and second liquid photopolymer resins comprises a conjugated polymer, a weak oxidant metal salt, a photopolymer and a photoinitiator such that at least one of the materials of the multi-material 3D structure is electrically conductive.

f) cleaning the photopolymerized structures when switching between the first and second liquid photopolymer resins to prevent contamination.

The present disclosure further provides a formulation for 3D printing of electrically conductive structures, comprising:

a conjugated polymer, a weak oxidant metal salt, a photopolymer and a photoinitiator, wherein upon 3D printing of the formulation followed by curing, a resulting 3D structure is electrically conductive.

A further understanding of the functional and advantageous aspects of the present disclosure can be realized by reference to the following detailed description and drawings.

### BRIEF DESCRIPTION OF THE DRAWINGS

Embodiments disclosed herein will be more fully understood from the following detailed description thereof taken in connection with the accompanying drawings, which form a part of this application, and in which:

FIG. 1 shows an elevation view of part of an apparatus for producing photopolymer structures using the Prior Art technique referred to herein as the “fixed-surface method”.

FIG. 2 shows an elevation view of part of an apparatus for producing photopolymer structures using a technique disclosed herein referred to herein as the “free-surface method”.

FIG. 3 shows a schematic of the DLP fabrication system in Example 1 for producing 3D structures according to the present disclosure.

FIG. 4 shows the emission spectrum of the projector and absorption spectrum of the H-Nu 470 photoinitiator.

FIG. 5 shows images of the pyramid structure throughout the fabrication process: (a) CAD model of the desired geometry, (b) pyramid geometry after slicing into 200 μm layer thicknesses, (c) optical image of the produced pyramid and (d) SEM image of the produced pyramid.

FIG. 6 shows a SEM image of the cross-section of a multi-layered hybrid PPy-UDMA polymer structure.

FIG. 7 shows EDAX elemental mapping of bright spots in the cross-section of the hybrid PPy-UDMA polymer structure.

FIG. 8 shows a cyclic voltammogram for the hybrid PPy-UDMA polymer in Example 1.

FIG. 9 is a plot of electrical conductivity of the hybrid polymer in Example 1 versus UDMA wt %.

FIG. 10 shows a schematic of the microfabrication vat polymerization additive manufacturing system in Example 2 for producing 3D structures according to the present disclosure.

FIG. 11 depicts the steps taken in the lamination procedure of the vat polymerization additive manufacturing process in Example 2.

FIG. 12 shows the emission spectrum of the UV light engine and absorption spectrum of the TPO photoinitiator and the Tinuvin 477 UV absorber used in Example 2.

FIG. 13 shows a 2.5 mm tall 3D Benchy torture test made from the hybrid PPy-BEMA photopolymer formulation using the microfabrication vat polymerization additive manufacturing system in Example 2.

FIG. 14 show a multi-material microfluidic channel with an embedded conjugated polymer pressure sensor fabricated with the microfabrication vat polymerization additive manufacturing system in Example 2.

FIG. 15 shows a cyclic voltammogram for the hybrid PPy-BEMA polymer in Example 2.

FIG. 16 is a plot of electrical conductivity of the hybrid polymer in Example 2 versus BEMA wt %.

FIG. 17 shows the typical response of a hybrid PPy-BEMA polymer sample under the cyclic tensile loading.

FIG. 18 shows the normalized resistance of the hybrid PPy-BEMA polymer sample at the stretched and relaxed states over 200 cycles.

FIG. 19 shows the gauge factor of the hybrid PPy-BEMA polymer sample over 200 loading cycles.

FIG. 20 shows the typical strain to break response of a hybrid PPy-BEMA polymer sample.

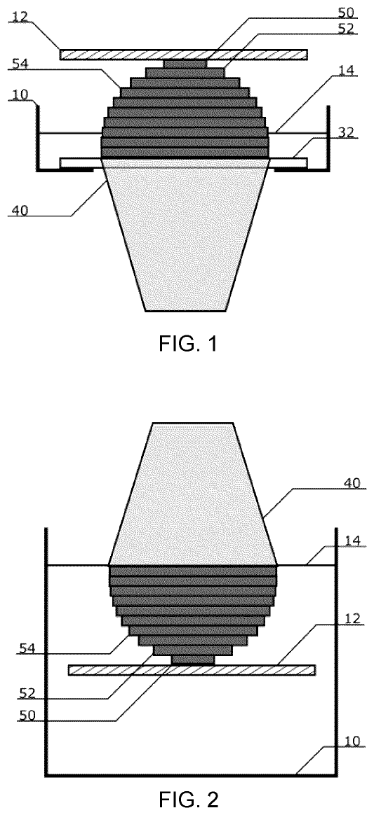

### DETAILED DESCRIPTION

Various embodiments and aspects of the disclosure will be described with reference to details discussed below. The following description and drawings are illustrative of the disclosure and are not to be construed as limiting the disclosure. The drawings are not to scale. Numerous specific details are described to provide a thorough understanding of various embodiments of the present disclosure. However, in certain instances, well-known or conventional details are not described in order to provide a concise discussion of embodiments of the present disclosure.

### Definitions

As used herein, the terms “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions.

### Definitions

As used herein, the phrase “conjugated polymer” refers to a polymer that possesses alternating single and double bonds along the polymer chain that allow electrons to be delocalized along the polymer chain. These polymers are also referred to as “intrinsically conductive polymers” since the delocalization of electrons along the polymer chain make this class of polymers capable of conducting electricity.

Examples of these conjugated polymers include, but are not limited to, include polypyrroles, polyanilines, polyphenylenes, polyfluorenes, polythiophenes or poly(oxythiophene)s.

As used herein, the phrase “weak oxidant metal salts” refers to an inorganic compound that has is unable to, or unable to rapidly oxidatively polymerize the conjugated polymer in the polymer formulation. The oxidizing strength may be increased by external energy such as light or heat, or by reacting with a secondary compound to increase the rate of polymerization of the conjugated polymer in the polymer formulation.

Examples of weak oxidant metal salts include, but are not limited to, silver salts such as silver nitrate, copper compounds such as [Cu(dpp)]²⁺ (dpp=2,9-diphenyl-1,10-phenanthroline), ruthenium compounds such as the ruthenium Ru(bpy)₃²⁺ (bpy=bipyrideine) and iron compounds such as those present in the photoinitiators Irgacure 261 and Komplex KM 1144.

As used herein, the phrase “photopolymer” refers to a monomer or oligomer which is added to the formulation with the conjugated polymer to improve the mechanical integrity of the overall polymer structure.

Examples of photopolymers that may be used include, but are not limited to, acrylate based photopolymers such as urethane dimethylacrylate (UDMA), Bisphenol A ethoxylate dimethacrylate (BEMA) and poly(ethylene glycol) methyl ether methacrylate (PEGMA) and epoxy based photopolymers such as Bisphenol A diglycidyl ether.

As used herein, the phrase “photoinitiator” refers to a compound that generates reactive species when irradiated with light to polymerize monomers and oligomers in the polymer formulation.

Examples of photoinitiators that may be used include, but are not limited to, Trimethylbenzoyl-diphenyl-phosphine oxide (TPO), 5,7-diiodo-3-butoxy-6-fluorone photoinitiator (H-Nu 470), 2,2-dimethoxy-2-phenylacetophenone (DMPA), 2-methoxy-2-phenyl-aceto phenone (BZME) and camphorquinone (CQ). The photoinitiator may be initiated by radiation of a visible light, UV, IR light source and an electron beam.

As used herein, the phrase “inhibitor” refers to a compound that has absorption properties similar to the utilized photoinitiator with the purpose of reducing the depth of radiation penetration. The use of an inhibitor improves the production of overhanging structures during 3D printing.

Two example fabrication systems and polymer formulations are presented. The first of which represents the initial prototype to investigate the fabrication of 3D hybrid ICP structures and the second example is the successor, designed to enable to the fabrication of microscale 3D hybrid ICP structures with improved material properties.

### EXAMPLE 1

### Investigation into the Fabrication of 3D Hybrid ICP Structures Vat Polymerization Additive Manufacturing System

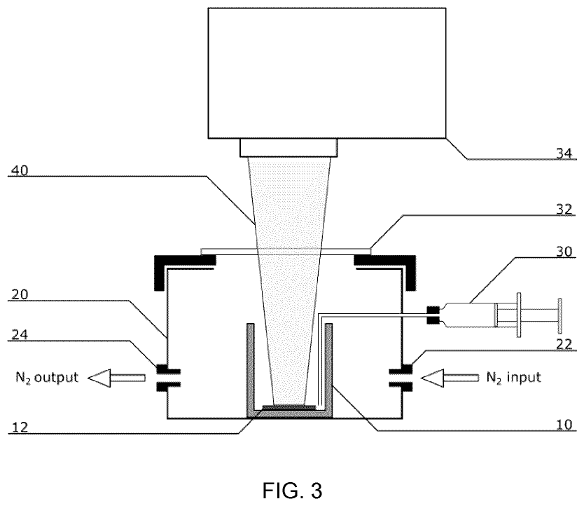

A non-limiting free-surface vat polymerization additive manufacturing system shown schematically in FIG. 3 was used to photopolymerize multilayered intrinsically conductive polymer structures using the present free-surface method. The free-surface method was used in this study due to the low stiffness of the hybrid polymer formulation that will break apart under the peeling forces present within the fixed-surface method. A syringe pump (30) was used to control the liquid level in the glass vat (10), but it will be appreciated that any other pump mechanism may be employed. The vat (10) was contained within a chamber (20) with a glass window in the top (32). A DLP projector (34) mounted above the chamber (20) projected images of each layer to selectively polymerize photopolymer layers onto the stainless steel build surface (12). Since the curing layer is exposed to air, oxygen inhibition must be considered. Oxygen dissolved at the top layer will react with radicals generated from the photoinitiator, drastically inhibiting polymerization. The chamber (20) was purged with an inert gas through an inlet (22) and outlet port (24) to compensate for this effect. A non-limiting inert gas is nitrogen. An embedded computer system is used to coordinate the additive manufacturing process. The embedded system is responsible for operating the syringe pump, communicating images to the DLP projector, and converting the input fabrication files into actuations to produce the desired structures.

While FIG. 3 shows the system using a light beam, it will be understood that other radiation beams may be used, for example, the beam of radiation may be produced by any one or combination of a visible light, UV, IR light source and an electron beam.

In the present free-surface method, thin layers of the photopolymer formulation are selectively cured on top of the previous layer to form the 3D object right-side up. The peeling force problem present in the fixed-surface method is eliminated by using the present free-surface method. More advanced techniques are required to control the cured layer thickness due to surface tension and this is achieved by controlled injection of the liquid using syringe pump (30) which is used to control the liquid level in the glass vat (10). Oxygen dissolved in the top layer of the polymer vat (10) will react with radicals generated from the photoinitiator, drastically inhibiting polymerization. The vat (10) is placed in an inert atmosphere to compensate for this effect. The free-surface method was developed due to the low stiffness of the hybrid polymer formulation.

The present method will now be illustrated with the following non-limiting example.

### Polymer Formulation

The polymer formulation contained the following reagents: Pyrrole (Sigma Aldrich, 131709), extended urethane dimethylacrylate (UDMA) (Esstech, Inc. X-726-0000), silver nitrate (Sigma Aldrich, 209139), and 5,7-diiodo-3-butoxy-6-fluorone photoinitiator (H-Nu 470) (Spectra Group Limited, Inc.).

The mechanical properties of the polymer formulation were modified by adding the UDMA polymer to the hybrid polymer mixture. This polymer is commonly used in photosensitive polymer resins to create a flexible polymer upon curing. The low stiffness of UDMA is beneficial for conductive polymer actuators which require large volume expansion and contraction.

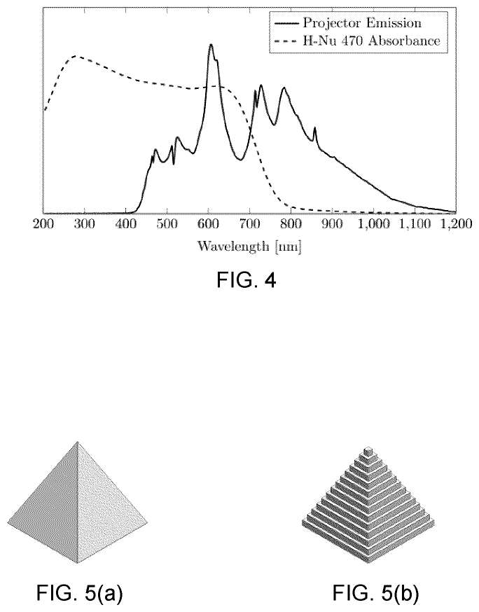

The photoinitiating system must generate reactive species to initiate polymerization of both the pyrrole and UDMA monomers when irradiated with light. Typical photosensitive resins are initiated with UV light; however, the output light spectrum of the projector, seen in FIG. 4, emits very little light within the UV spectrum so the photosensitive resin was designed to photopolymerize when irradiated with visible light. The H-Nu 470 photoinitiator was selected for the polymer formulation since its absorption spectrum, seen in FIG. 4, has a large overlap with the emission spectrum of the projector. A photoinitiator concentration of 0.1 wt. % was used in this formulation.

Pyrrole is known to polymerize with a cationic photoinitiator (see reference 10) while UDMA polymerizes with radical photoinitiation (see reference 16). The radical H-Nu 470 photoinitiator can directly photopolymerize UDMA, but radical sensitization of a cationic photoinitiator is required to initiate polymerization of pyrrole. Silver nitrate acts as both a co-initiator and dopant for the polymerization of pyrrole (see reference 11). Radicals from the H-Nu 470 photoinitiator excite silver cations which in turn initiate the polymerization of the pyrrole. The nitrate anion becomes incorporated along the PPy chain as a dopant. A 15:1 molar ratio of pyrrole to silver nitrate was used for all formulations since this ratio has been found to produce polypyrrole films with the greatest electrical conductivity (see reference 11).

### RESULTS AND DISCUSSION

### Pyramid Fabrication

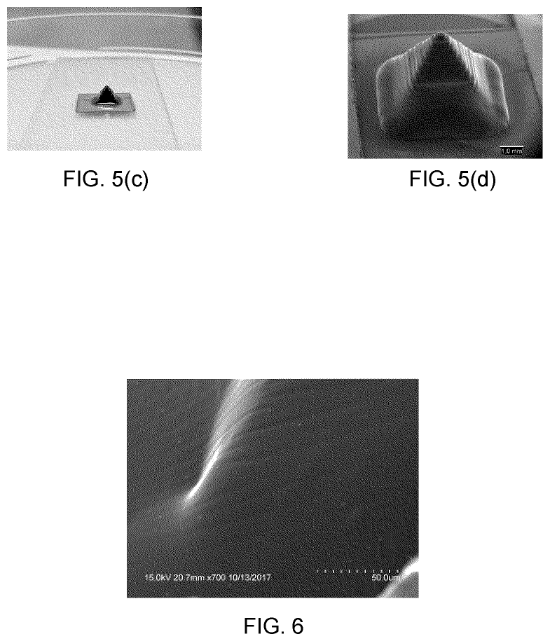

The DLP fabrication system shown in FIG. 3 was used to fabricate a 3D conductive polymer pyramid. The pyramid with a 4 mm by 4 mm base and a height of 3 mm was sliced into fourteen 200 μm thick layers seen in FIG. 5. Each layer was flooded with more than three times the required amount of photopolymer resin to allow the resin to flow over the previously cured layers before removing polymer to the required liquid level.

A polymer formulation containing 75 wt. % extended urethane dimethylacrylate (UDMA) was used to fabricate the pyramid. The higher concentration of UDMA was beneficial to the fabrication of 3D structures since the UDMA polymer photopolymerizes much faster than pyrrole. Pyrrole photopolymer formulations took in excess of 1 hour of irradiation to polymerize a solid layer while UDMA formulations took less than 2 minutes.

Furthermore, it was observed that the photopolymerized pyrrole created a particulate rather than a solid polymer layer that would scatter as polymer resin was dispensed and retracted from the polymer vat. Shorter irradiation times are beneficial to reducing the fabrication time of the produced structures along with improved achievable feature resolution since long irradiation times initiated polymerization outside the irradiated area. Further reduction in the layer thickness will reduce the required irradiation times leading to the ability to fabricate smaller and more complex structures. The hybrid polymer formulation takes advantage of the fast-curing UDMA to create a solid matrix that traps partially cured pyrrole. The pyrrole is fully cured as subsequent layers are irradiated along with a post-curing treatment. This phenomenon is apparent since the cured layer is initially translucent, characteristic of the UDMA polymer and darkens to an opaque black with further irradiation, which is characteristic of PPy.

The SEM image in FIG. 5d shows the layered structure of the pyramid. It can be seen that the top layers of the pyramid are more defined compared to the rounded bottom layers. This suggests there is curing outside the irradiated area of the bottom layers as subsequent layers above are irradiated. Further irradiation of each layer outside the vat of polymer may be required to fully cure each layer, inhibiting polymerization outside the area of the initial layers as subsequent layers are cured on top.

### Cross-Sectional Morphology and Composition Analysis

The cross-section of a four-layer hybrid photopolymer structure containing 75 wt % UDMA is shown in FIG. 6. The cross-section of the polymer samples was prepared by first embedding the soft polymer in a UV curable embedding medium before cryo-fracturing under liquid nitrogen. The rough surface of the cross-section was a result of the cryo-fracturing process. There is no evidence of layering artifacts are present in the cross-section of the polymer arising from the layer by layer fabrication method, however there are many bright spots present throughout the cross-section. SEM imaging was performed with a Hitachi S-3400N Microscope equipped with an Oxford Instruments INCA PentaFETx3 EDAX detector. Polymer samples were sputter coated with 60/40 Gold Palladium prior to imaging to minimize charging.

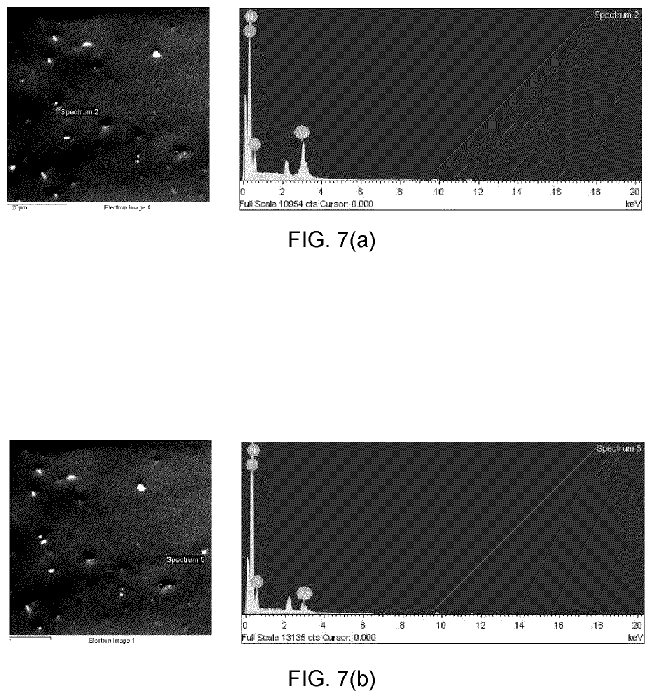

EDAX elemental mapping was performed to identify the chemical composition of the bright spots observed in the cross-section. FIG. 7a indicates the location and elemental composition of each site, and FIG. 7b indicates the location and elemental composition of the parent phase. EDAX elemental mapping revealed that the bright spots in the cross-section of the polymer structure contain a relatively high concentration of silver. It is postulated that these regions likely consist of PPy and silver due to the interaction between PPy and silver which is known to form Ag/PPy core shell nanoparticles (see references 28-30).

### Electrochemical Activity

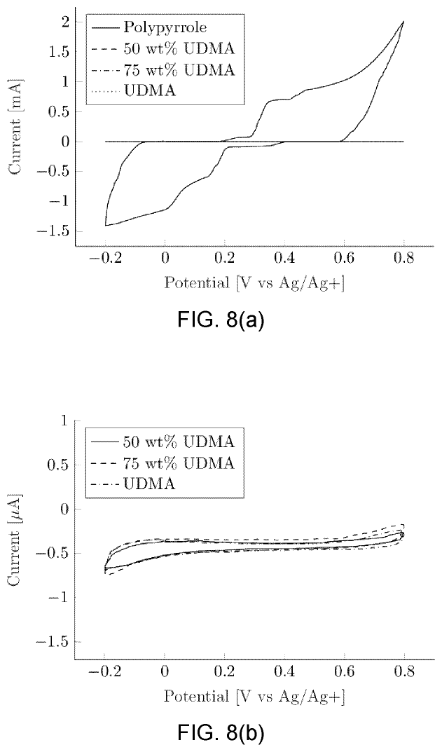

Cyclic voltammetry was performed on various polymer samples to elucidate their electrochemical activity. The cyclic voltammetry experiment was performed with a computer controlled Keithley 2611 source meter. Cycling was performed between 0.8 V and −0.2 V vs Ag/AgCl reference electrode at a scan rate of 20 mV/s in an aqueous NaNO₃ solution. FIG. 8a depicts the cyclic voltammogram of PPy with respect to polymer samples containing UMDA, while FIG. 8b isolates the data for samples containing the secondary UDMA polymer. The poor electrochemical activity observed for formulations containing UDMA is attributed to the high crosslink density of urethane acrylate polymers which greatly reduces the mobility of ionic species through the material. The network of urethane polymer surrounding the ionically conductive PPy regions effectively impedes ionic transport in the bulk. This reduced mobility results in all hybrid formulations containing UDMA exhibiting an ionic conductivity similar to that of pure UDMA.

### Electrical Conductivity

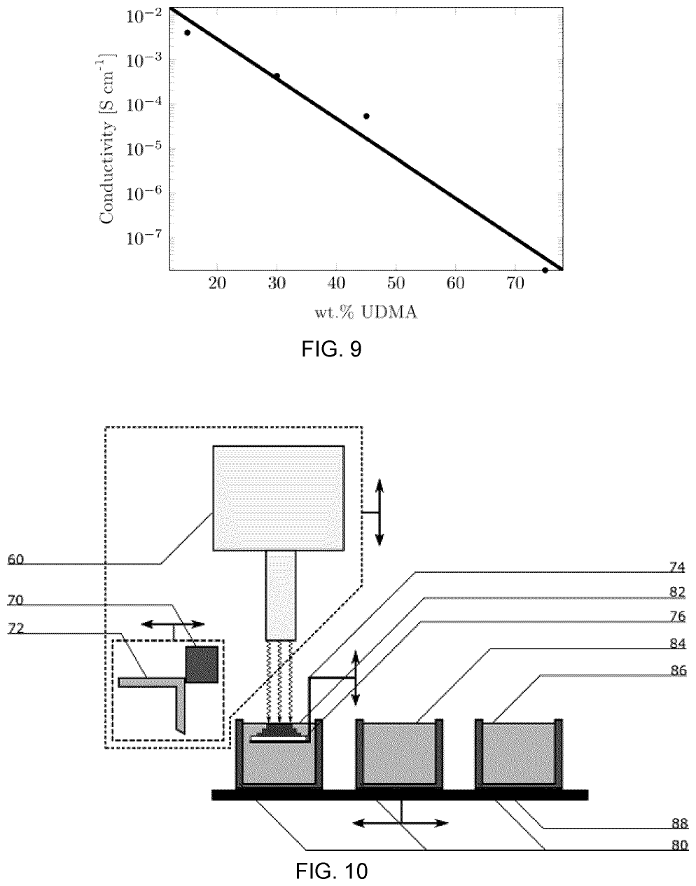

The electrical conductivity with respect to the concentration of UDMA can be seen in FIG. 9. As the concentration of the nonconducting UDMA polymer increased the conductivity of the hybrid material exponentially decreased. This relationship illustrates a trade off with this polymer formulation. A large relative concentration of UDMA is required to create a fast-curing polymer matrix that enables the selective polymerization and successive layer by layer fabrication of 3D structures. However, the lower concentration of pyrrole decreases the presence of smart material properties which are required for the creation of smart material enabled devices fabricated with this technology.

### EXAMPLE 2

### Microscale Fabrication of 3D Hybrid ICP Structures Microfabrication Vat Polymerization Additive Manufacturing System

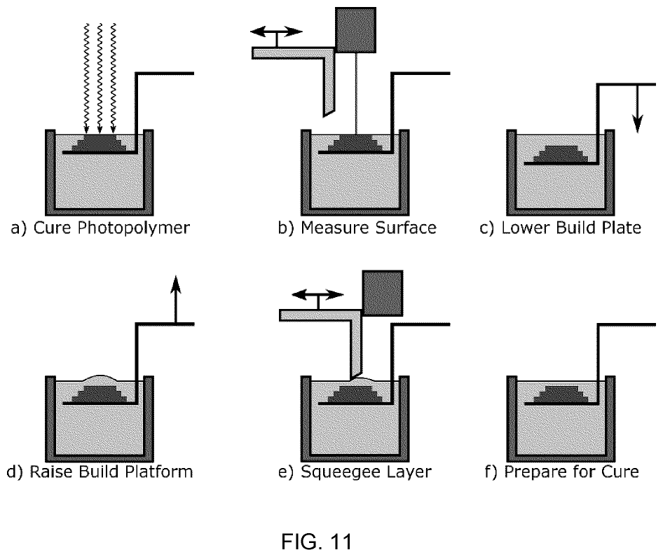

Based on the results from the system designed in Example 1, a second iteration of the vat polymerization additive manufacturing system was designed that is capable of fabricating microscale conjugated polymer structures. A schematic representation of the fabrication system can be seen in FIG. 10. This system consists of a UV DLP light engine (60) which can produce a projected pixel size of 5 μm. This feature resolution enables this system to fabricate microscale devices for target applications in the fields of MEMS and microfluidics. To realize a layer thickness resolution that is comparable to the projected pixel resolution, an advanced wiper laminating technique must be utilized. A build plate elevator (74) is vertically positioned in a prefilled photopolymer vat (80). Magnets are installed in the build plate elevator (74) so a build surface (76) may be easily attached and removed without needing to recalibrate the build plate surface between fabrication jobs. A wiper system (72) is required to remove excess photopolymer from the top of the previously cured layers since the surface tension forces between the liquid photopolymer and previously cured layer cause an uneven layer at small layer thicknesses when using conventional dip or syringe pump laminating techniques. A non-contact laser displacement sensor (70) is used to accurately measure the resin level in the photopolymer vat (80). FIG. 11 depicts the steps within the additive manufacturing process. After a 2D photopolymer layer has been cured (FIG. 11a), a non-contact laser displacement sensor first measures the height of the recently cured layer (FIG. 11b), then the build plate is dipped down into the photopolymer formulation (FIG. 11c) and finally the squeegee passes over the surface to form the fine layer thickness (FIG. 11e). The additive manufacturing process is coordinated with an embedded computer system. The embedded computer control system or microprocessor is responsible for moving the various motion stages, receiving sensor input from the laser displacement sensor, communicating images to the light engine, and converting the input fabrication files into actuations to produce the desired structures.

The volumetric expansion and contraction of conjugated polymer actuators are typically amplified with passive structures. The most common example of this technique is with the bilayer actuator where the conjugated polymer is coated onto a thin compliant film to transform the volume change of the conjugated polymer to large tip displacements. To take advantage of this technique, the microfabrication vat polymerization system incorporates multi-material fabrication.

To incorporate the multi-material feature, the system uses three polymer vats (80), one containing a commercially available photopolymer resin (86) for the passive structures, another for the active conjugated polymer (82) and the final vat containing a solvent (84) to wash the build plate when switching between polymer vats to prevent contamination.

A linear stage (88) is used to switch between the three vats.

### Polymer Formulation

The primary insight gained from the pyrrole-UDMA photopolymer in Example 1 was that the hybrid polymer formulation requires an ionically conductive secondary polymer that is compatible with polypyrrole. lonically conductive polymers are commonly used in the area of solid polymer electrolytes for battery applications. A popular solid polymer electrolyte is Bisphenol A ethoxylate dimethacrylate (BEMA, Sigma Aldrich, 455059) which is a flexible polymer that is compatible with electrolyte solutions including LiTFSI which is commonly used for polypyrrole actuators. Due to the high viscosity of the BEMA oligomer, it's typically combined with poly(ethylene glycol) methyl ether methacrylate (PEGMA, Sigma Aldrich, 447943) as a reactive diluent to achieve the desired viscosity.

The acrylate based polymers can be rapidly polymerized with a radical photoinitiator. Pyrrole-BEMA photopolymer formulations have been studied which form a solid polymer at a 41 wt % concentration of BEMA (see reference 15). This oligomer is promising for the present formulation since a lower concentration of the secondary polymer is required which may allow the smart material properties of polypyrrole to have a much greater impact on the overall properties of the hybrid polymer.

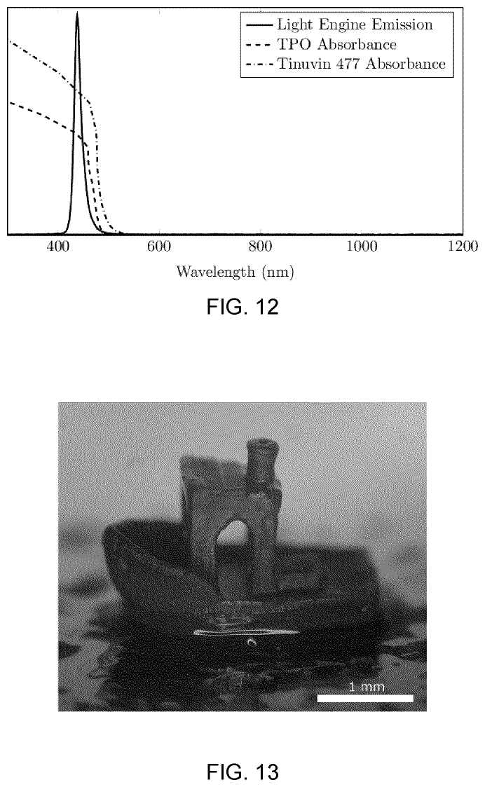

In this example, BEMA was diluted with PEGMA at a weight ratio of 7:3. A 40 wt % concentration of the BEMA and PEGMA solution was utilized as it was found to be the lowest concentration that could be employed without drastically impacting the mechanical integrity of the overall polymer. An 8:1 molar ratio of pyrrole to silver was used. The radical photoinitiator 2,4,6-Trimethylbenzoyl-diphenyl-phosphine oxide (TPO, IGM Resins) was added at a 5% concentration to both photopolymerize BEMA and PEGMA and sensitize the silver ions to polymerize the pyrrole monomer when irradiated with light from the UV light engine. TPO has a strong absorbance overlap with the emission spectrum of the light engine as shown in FIG. 12. To enable the fabrication of overhanging structures, the UV absorber Tinuvin 477 (Chemroy Canada Inc.) was incorporated into the photopolymer formulation at a concentration of 1%. The absorbance spectrum of Tinuvin 477 can also be found in FIG. 12. The emission spectrum of the light engine and absorption spectrum of the photoinitiator and UV absorber were measured with a BLACK-Comet UV-VIS spectrometer.

The pyrrole used in the pyrrole-BEMA hybrid formulation was distilled prior to use to improve the dissolution of silver nitrate in the monomer solution, eliminating the need for additional solvents. The pyrrole monomer is slightly unstable and will slowly polymerize in the absence of an initiating system. The solubility of silver nitrate decreases as the concentration of pyrrole oligomers increase in the monomer solution. Distilled pyrrole was stored in a fridge under a blanket of nitrogen to slow the rate of polymerization.

### 3D Structure Fabrication

The capability of the pyrrole-BEMA formulation to fabricate complex 3D structures was evaluated with the fabrication of a 2.5 mm tall 3D Benchy torture test shown in FIG. 13. Desirable results were obtained with the following fabrication parameters: a layer thickness of 25 μm, 30 s initial cure time to ensure adequate adhesion of the first layer to build plate, 1.5 s cure time for the following layers and a settling time of 30 s. The produced structures were rinsed with acetone and deionized water to remove uncured polymer from the fabricated part.

Overall, the pyrrole-BEMA formulation was able to fabricate the desired geometry of the 3D Benchy. The addition of Tinuvin 477 allowed the overhangs present in the roof structure to be accurately produced while also limiting to the amount of curing outside the irradiated areas. Fine features in the geometry such as the inner hole of the chimney and the rear fishing rod holder are slightly overcured. Reduced irradiation times caused the pillars holding up the roof to be too weak causing the roof of the boat to collapse, illustrating how the low stiffness of the pyrrole-BEMA photopolymer must be considered when designing 3D geometries with this material.

### Multi-Material Structure Fabrication

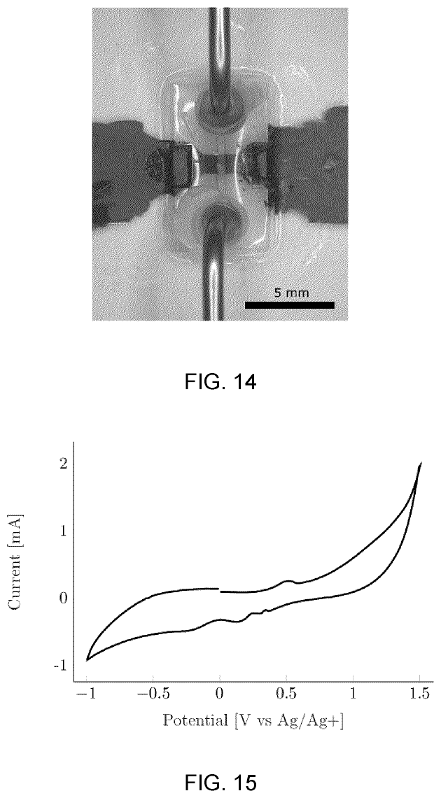

The multi-material feature of the microfabrication vat polymerization additive manufacturing system was applied to the fabrication of a prototype microfluidic channel with an embedded conjugated polymer pressure sensor. The device shown in FIG. 14, was fabricated in three stages: first, the base of the device was made from a conventional photopolymer, then the conjugated polymer sensing element was built and finally the microfluidic channel was built around the sensing element.

The central vat in the multi-material system was filled with acetone to clean the photopolymer structures when switching between polymer vats. Build plate was dried with nitrogen gas after acetone washing. The device was designed to have a thin sensing element to minimize the number of washing procedures.

### Electrochemical Activity

Cyclic voltammetry was performed on the hybrid polymer formulation to study the electrochemical activity. Polymer samples 9.6×6.4×0.5 mm in size were used for the experiment. The cyclic voltammetry experiment was performed with a similar method to that used for the PPY-UDMA polymer with a maximum potential of 1.5 V, a minimum potential of −1 V and a scan rate of 50 mV/s in an aqueous NaNO₃ solution. FIG. 15 depicts the cyclic voltammogram of the hybrid PPy-BEMA polymer. The electroactivity of the PPy-BEMA polymer was greatly improved compared to the PPy-UDMA formulation. This result illustrates an important material property of the hybrid polymer which is required for the development of conjugated polymer actuators.

### Electrical Conductivity

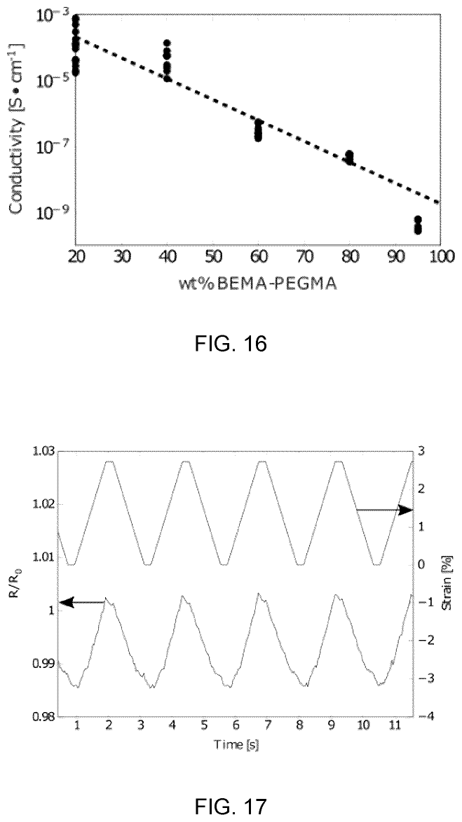

The electrical conductivity of the PPy-BEMA polymer was measured with the 4-point probe apparatus previously used for the PPy-UDMA hybrid polymer. The relationship between the concentration of BEMA-PEGMA in the photopolymer formulation and the resulting conductivity of the overall polymer is shown in FIG. 16. As with the UDMA secondary polymer, the electrical conductivity exponentially decreases with increasing concentration of the secondary polymer. The electrical conductivity of the various polymer samples was similar to the values observed with the PPy-UDMA hybrid polymer.

### Strain Sensing Performance

Conjugated polymers have also been investigated for advanced sensing technologies due to a change in their electrical conductivity in response to external stimuli. Conducting materials with piezoresistive properties may be used as strain sensors to detect small motions. The piezoresistive property of the hybrid PPy-BEMA polymer to evaluate its performance in strain sensing applications.

Tensile testing samples were fabricated in agreement with the ASTM D1708 standard (see reference 26). The samples were prepared using a cast PDMS mold of the desired geometry. The mold was filled with the polymer formulation and cured in a Spectroline XL 1500 UV crosslinker with 365 nm light for 30 minutes. A hybrid polymer formulation containing BEMA as the secondary polymer at a concentration of 40 wt % was used for the piezoresistive experiments.

Piezoresistive testing was performed with a CellScale UniVert materials testing instrument equipped with 10 N load cell. The resistance of the samples was measured using a Keithley 2611 source meter. For cyclic testing, samples were stretched to a maximum strain of 3% at a rate of 8 mm/min, held at the maximum stretched position for 1 s, returned to its original length at a rate of 8 mm/min, and held at the relaxed position for 1 s. This displacement protocol was repeated for 200 cycles, and resistivity measurements were obtained at a rate of 5 Hz. Post-cyclic testing, the samples were further displaced in tension at a rate of 3 mm/min to failure.

### Cyclic Strain Response

The typical response of the polymer sample under the cyclic tensile loading is shown in FIG. 17. The amount of strain is indicated by the red line and the resistance of the polymer sample is shown by the blue line. As the strain on the polymer increased, the measured resistance of the polymer sample also increased.

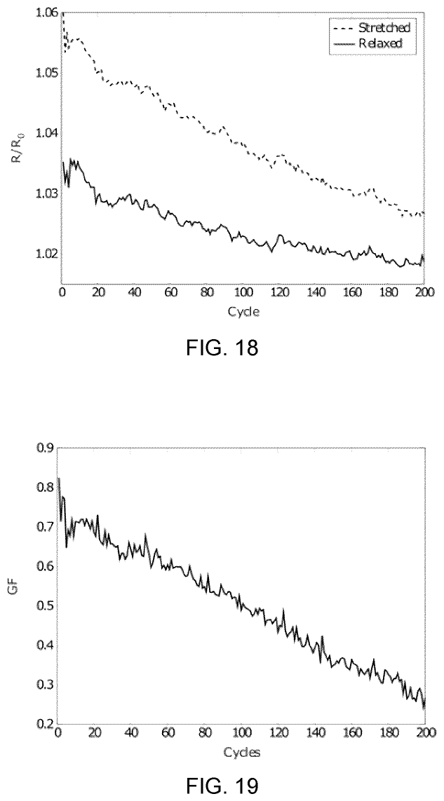

The normalized resistance at the stretched and relaxed states over 200 cycles is shown in FIG. 18, which illustrates a gradual decay in the nominal resistance, indicated by the decay of the resistance in the relaxed state. There is also a decrease in the piezoresistive response when subject to the 3% strain, indicated by a decreasing distance between the relaxed and stretched resistance over time. The decay in the piezoresistive response is clearly shown in FIG. 19 with a plot of gauge factor over the 200 loading cycles. The gauge factor of the material linearly decays with increased cycling.

The range of gauge factors measured with the hybrid conjugated polymer samples is similar to the work performed by Mu Q. et al who observed a gauge factor of 0.37 for polymer based strain sensors containing carbon nanotubes (see reference 27).

### Strain to Break Response

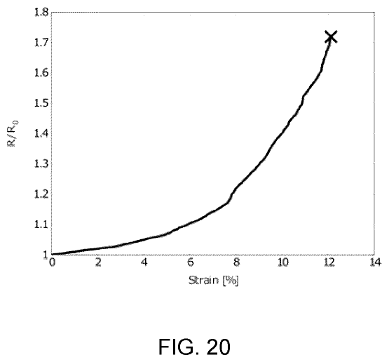

FIG. 20 shows a typical strain to break experiment with a plot of normalized resistance versus strain. The resistance of the tensile testing sample exponentially increased with strain. Based on six (6) samples, the average strain to failure was 13%, illustrating the flexible nature of the hybrid polymer formulation.

### CONCLUSION

A photosensitive pyrrole formulation for use with DLP 3D printing technology disclosed herein. The components of a photopolymer formulation were presented along with the design of a DLP 3D printing fabrication system to grow the objects using a “free-surface” method as disclosed herein. The DLP fabrication system was used to fabricate a multilayered 3D pyramid structure to demonstrate the capability of this technique. The DLP technique enables the fabrication of a new class of 3D ICP structures with complex features. ICP actuators made with this technique will be capable of complex actuation tasks such as torsion or multiple degree-of-freedom actuation.

### REFERENCES

1. Jager, E. W. H., “Microfabricating Conjugated Polymer Actuators,” Science 290(5496), 1540-1545 (2000).
2. Hara, S., Zama, T., Takashima, W., and Kaneto, K., “Artificial Muscles Based on Polypyrrole Actuators with Large Strain and Stress Induced Electrically,” Polymer Journal 36(2), 151-161 (2004).
3. Price, A. D., “Photopolymerization of 3D conductive polypyrrole structures via digital light processing,” in [Electroactive Polymer Actuators and Devices (EAPAD) 2016], 9798(1), Proc. SPIE (2016).
4. Shoa, T., Madden, J. D., Fok, C. W. E., and Mirfakhrai, T., “Rate Limits in Conducting Polymers,” Advances in Science and Technology 61, 26-33 (2008).
5. Yamada, K., Yamada, Y., and Sone, J., “Three-dimensional photochemical microfabrication of poly(3,4ethylene-dioxythiophene) in transparent polymer sheet,” Thin Solid Films 554(2), 102-105 (2014).
6. Yamada, K., Watanabe, M., and Sone, J., “Three-dimensional printing of conducting polymer microstructures into transparent polymer sheet: Relationship between process resolution and illumination conditions,” Optical Review 21(5), 679-682 (2014).
7. Sone, J., Yamada, K., Asami, A., and Chen, J., “Sub-Micrometer Size Structure Fabrication Using a Conductive Polymer,” Micromachines 6(1), 96-109 (2014).
8. Kern, J.-M. and Sauvage, J.-P., “Photochemical deposition of electrically conducting polypyrrole,” Journal of the Chemical Society, Chemical Communications (10), 657-658 (1989).
9. Yamada, K., Kimura, Y., Suzuki, S., Sone, J., Chen, J., and Urabe, S., “Multiphoton-sensitized Polymerization of Pyrrole,” Chemistry Letters 35(8), 908-909 (2006).
10. Asmussen, S., Arenas, G., and Vallo, C., “Photopolymerization of pyrrole/methacrylate mixtures using α-cleavage type photoinitiators in combination with iodonium salt,” Synthetic Metals 209, 304-312 (2015).
11. Hodko, D., Gamboa-Aldeco, M., and Murphy, O. J., “Photopolymerized silver-containing conducting polymer films. Part I. An electronic conductivity and cyclic voltammetric investigation,” Journal of Solid State Electrochemistry 13(7), 1063-1075 (2009).
12. Migahed, M., Fahmy, T., Ishra, M., and Barakat, A., “Preparation, characterization, and electrical conductivity of polypyrrole composite films,” Polymer Testing 23(3), 361-365 (2004).
13. Campomanes, R., Bittencourt, S., and Campos, J., “Study of conductivity of polypyrrol-poly(vinyl alcohol) composites obtained photochemically,” Synthetic Metals 102(1-3), 1230-1231 (1999).
14. Rinaldi, A., Kunita, M., Santos, M., Radovanovic, E., Rubira, A., and Girotto, E., “Solid phase photopolymerization of pyrrole in poly(vinylchloride) matrix,” European Polymer Journal 41(11), 2711-2717 (2005).
15. Ijeri, V. S., Nair, J. R., Gerbaldi, C., Gonnelli, R. S., Bodoardo, S., and Bongiovanni, R. M., “An elegant and facile single-step UV-curing approach to surface nano-silvering of polymer composites,” Soft Matter 6(19), 4666-4668 (2010).
16. Yang, Y., Urbas, A., Gonzalez-Bonet, A., Sheridan, R. J., Seppala, J. E., Beers, K. L., and Sun, J., “A composition-controlled cross-linking resin network through rapid visible-light photo-copolymerization,” Polym. Chem. 7(31), 5023-5030 (2016).
17. Kengo Kobayashi and Koji Ikuta, “Advanced free-surface microstereolithography with 10μ resolution for hybrid microstructures,” in [2007 IEEE/ASME international conference on advanced intelligent mechatronics], 1-6, IEEE (2007).
18. Ligon, S. C., Husár, B., Wutzel, H., Holman, R., & Liska, R. (2014). Strategies to Reduce Oxygen Inhibition in Photoinduced Polymerization. Chemical Reviews, 114(1), 557-589.
19. Cullen, A. T., & Price, A. D. (2018). Digital light processing 3D printing of intrinsically conductive polymer structures. Synthetic Metals, 235 (November 2017), 34-41.
20. Sun, C., Fang, N., Wu, D. M., & Zhang, X. (2005). Projection micro-stereolithography using digital micro-mirror dynamic mask. Sensors and Actuators, A: Physical, 121(1), 113-120.
21. Choi, J., Wicker, R. B., Cho, S., Ha, C., & Lee, S. (2009). Cure depth control for complex 3D microstructure fabrication in dynamic mask projection microstereolithography. Rapid Prototyping Journal, 15(September 2008), 59-70.
22. Spinks, G. M., Alici, G., McGovern, S., Xi, B., & Wallace, G. G. (2009). Conjugated Polymer Actuators: Fundamentals. In Biomedical Applications of Electroactive Polymer Actuators (pp. 193-227). John Wiley & Sons, Ltd.
23. Rabek, J. F., Lucki, J., Zuber, M., Qu, B. J., & Shi, W. F. (1992). Polymerization of pyrrole by cationic photoinitiators. Polymer, 33(22), 4838-4844.
24. Mohandass, C., Vijayaraj, A. S., Rajasabapathy, R., Satheeshbabu, S., Rao, S. V, Shiva, C., & De-Mello, I. (2013). Biosynthesis of Silver Nanoparticles from Marine Seaweed Sargassum cinereum and their Antibacterial Activity. Indian Journal of Pharmaceutical Sciences, 75(5), 606-10.
25. Segawa, H., Shimidzu, T., & Honda, K. (1989). A novel photo-sensitized polymerization of pyrrole. Journal of the Chemical Society, Chemical Communications, 2(132), 132-133.
26. ASTM. (2014). Standard Test Method for Tensile Properties of Plastics by Use of Microtensile Specimens. American Society for Testing and Materials, 8(October), 5-9.
27. Mu, Q., Wang, L., Dunn, C. K., Kuang, X., Duan, F., Zhang, Z., . . . Wang, T. (2017). Digital light processing 3D printing of conductive complex structures. Additive Manufacturing, 18(November 2017), 74-83.
28. Kasisomayajula, S., Jadhav, N., & Gelling, V. J. (2016). Conductive polypyrrole and acrylate nanocomposite coatings: Mechanistic study on simultaneous photopolymerization. Progress in Organic Coatings, 101, 440-454.
29. Yang, X., & Lu, Y. (2005). Preparation of polypyrrole-coated silver nanoparticles by one-step UV-induced polymerization. Materials Letters, 59(19-20), 2484-2487.
30. Nazar, R., Ronchetti, S., Roppolo, I., Sangermano, M., & Bongiovanni, R. M. (2015). In situ synthesis of polymer embedded silver nanoparticles via photopolymerization. Macromolecular Materials and Engineering, 300(2), 226-233.

1. A method for producing an electrically conductive 3D structure, comprising:
a) immersing a substrate having a build surface into a vat containing a liquid photopolymer resin, the liquid photopolymer resin comprising a conjugated polymer, a weak oxidant metal salt, a photopolymer and a photoinitiator;
b) controlling a layer of the liquid photopolymer resin on the build surface so that when the liquid photopolymer resin is photopolymerized a base resin layer of preselected thickness is produced;
c) projecting a beam of radiation having a preselected pattern down onto a top surface of the first layer of the liquid photopolymer resin for long enough to effect photopolymerization of the layer of liquid photopolymer resin, and
d) repeating step a), b) and c) a plurality of times on top of the base layer such each layer of the 3D structure is selectively photopolymerized on top of the previously photopolymerized layer to produce the electrically conductive 3D structure.

2. The method according to claim 1 wherein step b) of controlling a thickness of the layer of the liquid photopolymer resin is achieved by using a pump used to control the liquid photopolymer resin level in the vat or by controlling the vertical position of the build surface within a prefilled vat.

3. The method according to claim 1 wherein the vat is contained within a chamber with a transparent window in the top through which the beam of radiation is directed.

4. The method according to claim 3 wherein chamber is purged with an inert gas through an inlet and outlet port to prevent oxygen inhibition during photopolymerization of the layer of liquid photopolymer resin.

5. The method according to claim 1 wherein the vat is blanketed with an inert gas to prevent oxygen inhibition during photopolymerization of the layer of liquid photopolymer resin.

6. The method according to claim 1 wherein the beam of radiation is a light beam produced by a digital light projector mounted above the chamber.

7. The method according to claim 1 wherein the beam of radiation is produced by any one or combination of a visible light, UV, IR light source and an electron beam.

8. The method according to claim 1 wherein the build surface is magnetically detachable.

9. The method according to claim 1, wherein the conjugated polymers include any one or combination of polypyrroles, polyanilines, polyphenylenes, polyfluorenes, polythiophenes and poly(oxythiophene)s.

10. The method according to claim 1 wherein the weak oxidant is any one or combination silver salts, copper compounds, ruthenium compounds, and iron compounds.

11. The method according to claim 10 wherein the silver salt is silver nitrate, silver nitrite, silver tosylate, silver perchlorate, and silver tetrafluoroborate.

12. The method according to claim 10 wherein the copper compound is [Cu(dpp)]²⁺ (dpp=2,9-diphenyl-1,10-phenanthroline)

13. The method according to claim 10 wherein the ruthenium compound is a ruthenium complex Ru(bpy)₃²⁺ (bpy=bipyrideine).

14. The method according to claim 10 wherein iron compounds are those present in photoinitiators Irgacure 261 and Komplex KM 1144.

15. The method according to claim 1, wherein said photoinitiator includes any one or combination of Trimethylbenzoyl-diphenyl-phosphine oxide (TPO), 5,7-diiodo-3-butoxy-6-fluorone photoinitiator (H-Nu 470), 2,2-dimethoxy-2-phenylacetophenone (DMPA), 2-methoxy-2-phenyl-aceto phenone (BZME) and camphorquinone (CQ).

16. The method according to claim 1, wherein the photopolymer includes any one of acrylate based photopolymers and epoxy based photopolymers.

17. The method according to claim 16, wherein the acrylate based photopolymers include any one of urethane dimethylacrylate (UDMA), Bisphenol A ethoxylate dimethacrylate (BEMA) and poly(ethylene glycol) methyl ether methacrylate (PEGMA).

18. The method according to claim 16, wherein the epoxy based photopolymers include Bisphenol A diglycidyl ether.

19. The method according to claim 1, wherein the liquid photopolymer resin further comprises an inhibitor compound that has absorption properties similar to the photoinitiator for the purpose of reducing the depth of radiation penetration.

20. The method according to claim 1, wherein the liquid photopolymer resin further comprises conductive particles.

21. The method according to claim 20, wherein the conductive particles includes any one or combination of carbon nanotubes, graphene nanoparticles and metal nanoparticles.

22. A method for producing a multi-component 3D structure with one of the components being electrically conductive, comprising:
a) immersing a substrate having a build surface into a vat containing a first liquid photopolymer resin;
b) controlling a layer of the first liquid photopolymer resin on the build surface so that when the first liquid photopolymer resin is photopolymerized a base resin layer of preselected thickness is produced;
c) projecting a beam of radiation having a preselected pattern down onto a top surface of the first layer of the liquid photopolymer resin for long enough to effect photopolymerization of the layer of liquid photopolymer resin, and
d) repeating step a), b) and c) a preselected number of times on top of the base layer such each layer of the 3D structure is selectively photopolymerized on top of the previously photopolymerized layer to produce a 3D structure of preselected dimensions; and
e) repeating steps a) to d) using a second liquid photopolymer resin which is different from the first liquid photopolymer resin to give a multi-material 3D structure of preselected dimensions, wherein one of the first and second liquid photopolymer resins comprises a conjugated polymer, a weak oxidant metal salt, a photopolymer and a photoinitiator such that at least one of the materials of the multi-material 3D structure is electrically conductive.
f) cleaning the photopolymerized structures when switching between the first and second liquid photopolymer resins to prevent contamination.

23. A formulation for 3D printing of electrically conductive structures, comprising:
a conjugated polymer, a weak oxidant metal salt, a photopolymer and a photoinitiator, wherein upon 3D printing of the formulation followed by curing, a resulting 3D structure is electrically conductive.

24. The formulation according to claim 23, wherein the conjugated polymers include any one or combination of polypyrroles, polyanilines, polyphenylenes, polyfluorenes, polythiophenes and poly(oxythiophene)s.

25. The formulation according to claim 23, wherein the photopolymer includes any one of acrylate based photopolymers and epoxy based photopolymers.

26. The formulation according to claim 25, wherein the acrylate based photopolymers include any one of urethane dimethylacrylate (UDMA), Bisphenol A ethoxylate dimethacrylate (BEMA) and poly(ethylene glycol) methyl ether methacrylate (PEGMA).

27. The formulation according to claim 25, wherein the epoxy based photopolymers include Bisphenol A diglycidyl ether.

28. The formulation according to claim 23, wherein the weak oxidant is any one or combination silver salts, copper compounds, ruthenium compounds, and iron compounds.

29. The formulation according to claim 28, wherein the silver salt is any one of silver nitrate, silver nitrite, silver tosylate, silver perchlorate, and silver tetrafluoroborate, and wherein the copper compound is [Cu(dpp)]²⁺ (dpp=2,9-diphenyl-1,10-phenanthroline), and wherein the ruthenium compound is a ruthenium complex Ru(bpy)₃²⁺ (bpy=bipyrideine), and wherein the iron compounds are those present in photoinitiators Irgacure 261 and Komplex KM 1144.

30. The formulation—according to claim 23, wherein said photoinitiator includes any one or combination of Trimethylbenzoyl-diphenyl-phosphine oxide (TPO), 5,7-diiodo-3-butoxy-6-fluorone photoinitiator (H-Nu 470), 2,2-dimethoxy-2-phenylacetophenone (DMPA), 2-methoxy-2-phenyl-aceto phenone (BZME) and camphorquinone (CQ).
